(19) United States
(12) Patent Application Publication
(10) Pub. No.: US 2011/0030790 A1
(43) Pub. Date: Feb. 10, 2011

(54) Solar cell modules and methods of manufacturing the same

(75) Inventors: Young-jun Park, Suwon-si (KR); Jong-min Kim, Suwon-si (KR); Seung-nam Cha, Seoul (KR); Hyung-bin Son, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/656,292

(22) Filed: Jan. 25, 2010

(30) Foreign Application Priority Data
Aug. 4, 2009 (KR) 10-2009-0071713

(51) Int. Cl. H01L 31/00; H01L 31/18; H01L 31/0232

(52) U.S. Cl. 136/259; 438/72; 257/E31.127

(57) ABSTRACT

A solar cell module includes an upper substrate including a cylindrical lens is disposed on a lower substrate to cover a solar cell. The cylindrical lens focuses incident light onto the solar cell. In a method of manufacturing the solar cell module, a solar cell is formed on a lower substrate by sequentially depositing a first material layer, a second material layer, and a second electrode onto the first electrode. An upper substrate including a cylindrical lens is adhered to or formed on the lower substrate.

### CROSS-REFERENCE TO RELATED APPLICATION(S)

This application claims priority under 35 U.S.C. §119 to Korean Patent Application No. 10-2009-0071713, filed on Aug. 4, 2009, in the Korean Intellectual Property Office, the disclosure of which is incorporated herein in its entirety by reference.

### BACKGROUND

1. Field

One or more example embodiments relate to solar cell modules and methods of manufacturing the same.

2. Description of the Related Art

A conventional solar cell module is formed by disposing a protective film over a top and bottom of a solar cell, and covering the protective film with a glass substrate and a cover film. In this example, an ethylene-vinyl acetate (EVA) film, which is a synthetic resin, is often used as the protective film for protecting the solar cell. However, such a conventional solar cell module is effective only when sunlight is perpendicularly incident on the solar cell module, and the efficiency of the solar cell changes when an optical path of sunlight changes over time. Accordingly, the solar cell module is only usable for a limited time, which decreases efficiency of the solar cell module.

A light tracing apparatus or a tracker system may be used to increase the efficiency of the solar cell module. But, in doing so the solar cell module becomes more complex and the costs of the solar cell module increase because separate equipment is required for the light tracing apparatus or tracker system.

In addition, a solar cell module is intended to be used for a relatively long period of time (e.g., about 20 years or more). During this time, solar cell modules are exposed to external conditions, which may change characteristics of the solar cell. The EVA film described above may protect the solar cell module. But, the EVA film is relatively expensive, and thus, increases the cost of the solar cell module.

### SUMMARY

One or more example embodiments provide solar cell modules and methods of manufacturing the same.

According to one or more example embodiments, a solar cell module includes: a lower substrate; a solar cell disposed on the lower substrate; and an upper substrate disposed on the lower substrate to cover the solar cell. The upper substrate includes a cylindrical lens that focuses sunlight onto the solar cell.

According to one or more example embodiments, a solar cell module includes: a lower substrate; an upper substrate disposed on the lower substrate; and a solar cell disposed between the upper and lower substrates. The upper substrate is disposed to cover the solar cell, and includes a cylindrical lens that focuses sunlight onto the solar cell.

According to at least some example embodiments, a midsection of the cylindrical lens may be thicker than ends thereof. The solar cell may be disposed at a focal length of the cylindrical lens. A space between the lower substrate and the cylindrical lens may be sealed, and the solar cell may be disposed in the space. The sealed space may be vacuous or filled with an inert gas. The solar cell may have a p-n junction structure or a p-i-n junction structure. The solar cell may be a silicon (Si) crystalline solar cell, an Si thin film solar cell, a copper indium gallium selenide (CIGS) thin film solar cell, a cadmium telluride (CdTe) thin film solar cell, a III-V group semiconductor solar cell, or an organic solar cell.

According to one or more example embodiments, a solar cell module includes: a lower substrate; a reflective layer formed on the lower substrate; and an upper substrate disposed on the lower substrate. The upper substrate further includes a cylindrical lens. The solar cell module further includes: a solar cell disposed in a space between the lower substrate and the cylindrical lens. The cylindrical lens focuses light onto the solar cell.

According to at least some example embodiments, the cylindrical lens may focus sunlight onto the solar cell, and the reflective layer may reflect light that reaches the reflective layer without being focused onto the solar cell toward the solar cell. The solar cell may be disposed at a focal length of the cylindrical lens and at a focal length of the reflective layer.

The reflective layer may be a thin metal layer or a thin dielectric layer. A top surface of the lower substrate may be a concave surface. The concave surface may correspond to the cylindrical lens. The reflective layer may be formed on the concave surface. The bottom surface of the lower surface may be a convex surface, which corresponds to the concave surface. In the alternative, the reflective layer may be formed on the convex surface. In this case, the lower substrate may be a transparent substrate.

One or more example embodiment provides a method of manufacturing a solar cell module. According to at least one example embodiment, a concave surface is formed on a lower substrate, and a reflective layer is formed on the concave surface. A first electrode having a wire shape is prepared by using a support inside the concave surface, and a solar cell is manufactured by sequentially depositing a first material layer, a second material layer, and a second electrode onto the first electrode. An upper substrate including a cylindrical lens is adhered on the lower substrate.

At least one other example embodiment provides a method of manufacturing a solar cell module. According to at least this example embodiment, a reflective layer is formed on a surface of a lower substrate. The surface is one of a concave and convex surface. A first electrode having a wire shape is prepared, and a solar cell is manufactured by sequentially depositing a first material layer, a second material layer, and a second electrode onto the first electrode. An upper substrate including a cylindrical lens is adhered on the lower substrate.

### BRIEF DESCRIPTION OF THE DRAWINGS

Example embodiments will become apparent and more readily appreciated from the following description of the accompanying drawings of which:

FIG. 1 a laid-open perspective view illustrating a solar cell module according to an example embodiment;

FIG. 2 is a cross-sectional view taken along a line II-II′ of FIG. 1;

FIG. 3 is a cross-sectional view of an example embodiment of the solar cell illustrated in FIG. 1;

FIG. 4 is a cross-sectional view of another example embodiment of the solar cell illustrated in FIG. 1;

FIG. 5 is a laid-open perspective view illustrating a solar cell module according to another example embodiment;

FIG. 6 is a laid-open perspective view illustrating a solar cell module according to yet another example embodiment;

FIG. 7 is a cross-sectional view taken along a line VII-VII′ of FIG. 6;

FIG. 8 is a cross-sectional view of an example embodiment of the solar cell illustrated in FIG. 6;

FIG. 9 is a cross-sectional view of another example embodiment of the solar cell illustrated in FIG. 6;

FIGS. 10 and 11 are diagrams for describing a method of manufacturing a solar cell module according to an example embodiment;

FIG. 12 is a cross-sectional view illustrating a solar cell module according to yet another example embodiment; and

FIG. 13 is a cross-sectional view illustrating a solar cell module according to another example embodiment.

### DETAILED DESCRIPTION

Example embodiments will now be described more fully with reference to the accompanying drawings, in which some example embodiments are shown. In the drawings, the thicknesses of layers and regions are exaggerated for clarity. Like reference numerals in the drawings denote like elements. In the drawings, the thicknesses of layers and regions are exaggerated for clarity.

Detailed illustrative embodiments are disclosed herein. However, specific structural and functional details disclosed herein are merely representative for purposes of describing example embodiments. Example embodiments may, however, may be embodied in many alternate forms and should not be construed as limited to only the example embodiments set forth herein.

It should be understood, however, that there is no intent to limit the general inventive concept to the particular example embodiments disclosed, but on the contrary example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Various example embodiments of the present invention will now be described more fully with reference to the accompanying drawings in which some example embodiments of the invention are shown. In the drawings, the thicknesses of layers and regions are exaggerated for clarity.

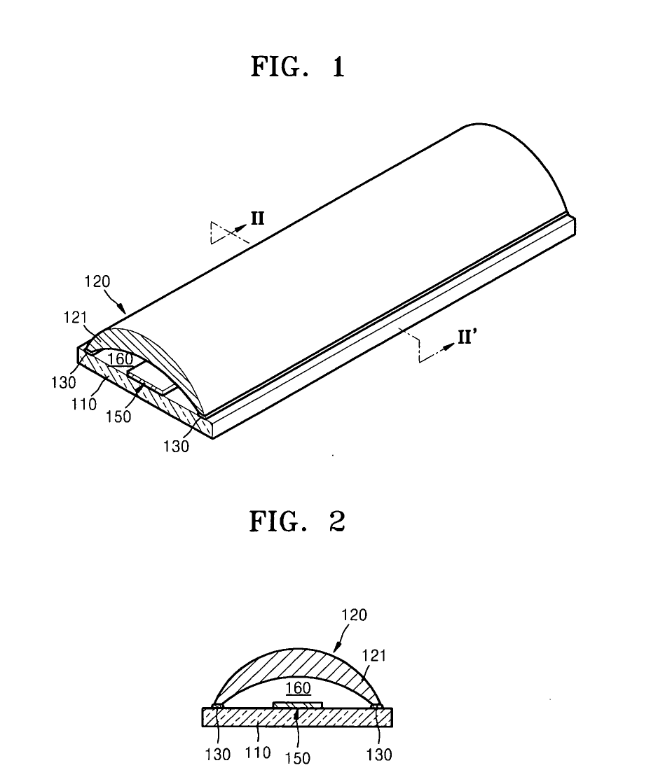

FIG. 1 a laid-open perspective view illustrating a solar cell module according to an example embodiment. FIG. 2 is a cross-sectional view taken along a line II-II′ of FIG. 1.

Referring to FIGS. 1 and 2, the solar cell module includes a lower substrate 110, a solar cell 150 disposed on the lower substrate 110, and an upper substrate 120 disposed on the lower substrate 110. The upper substrate 120 covers the solar cell 150. The lower substrate 110 may be formed of any one of various materials, such as silicon, glass, plastic, or metal.

The solar cell 150 is prepared on a top surface of the lower substrate 110. In one example embodiment, the solar cell 150 has a strip shape. However, the shape of the solar cell 150 is not limited thereto. A plurality of solar cells 150 may be arranged on the lower substrate 110 in a line.

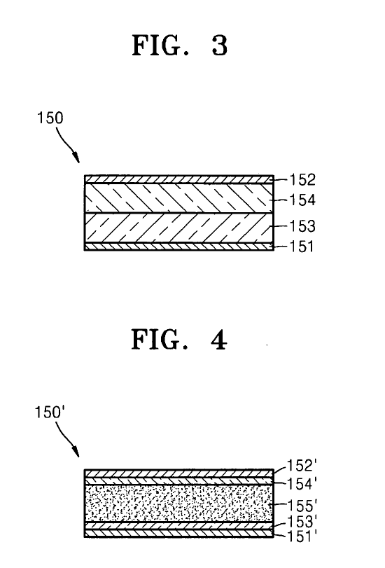

FIG. 3 is a cross-sectional view of an example embodiment of the solar cell 150 illustrated in FIG. 1.

As illustrated in FIG. 3, the solar cell 150, according to this example embodiment, has a p-n junction structure. In more detail, the solar cell 150 has a structure in which a first material layer 153, a second material layer 154, and a second electrode 152 are sequentially disposed on a first electrode 151 in the stated order. The first material layer 153 may be a p-type material layer and the second material layer 154 may be an n-type material layer. Alternatively, the first material layer 153 may be an n-type material layer and the second material layer 154 may be a p-type material layer.

According to example embodiments, the solar cell 150 may be any type of solar cell. For example, the solar cell 150 may be a silicon (Si) crystalline solar cell, a Si thin film solar cell, a copper indium gallium selenide (CIGS) thin film solar cell, a cadmium telluride (CdTe) thin film solar cell, a III-V group semiconductor solar cell, an organic solar cell, etc. However, the solar cell 150 is not limited thereto.

FIG. 4 illustrates another example embodiment of a solar cell. The solar cell 150′ illustrated in FIG. 4 has a p-i-n junction structure. In this example, the solar cell 150′ has a structure including an intrinsic material layer 155′ formed between a first material layer 153′ and a second material layer 154′. The first and second material layers 153′ and 154′ may each be about 10 nm to 20 nm, inclusive, thick. The intrinsic material layer 155′ may be about 300 nm to 500 nm, inclusive, thick. However, the thicknesses of the first and second material layers 153′ and 154′ and the thickness of the intrinsic material layer 155′ are not limited thereto.

A first electrode 151′ is formed on a bottom surface of the first material layer 153′ and a second electrode 152′ is formed on a top surface of the second material layer 154′.

Referring back to FIGS. 1 and 2, the upper substrate 120 is formed over the solar cell 150 to cover the solar cell 150. According to at least this example embodiment, the upper substrate 120 includes a cylindrical lens 121 disposed along the solar cell 150. The cylindrical lens 121 focuses incident light (e.g., sunlight) onto the solar cell 150. In the example shown in FIG. 1, the cylindrical lens 121 is a lens having at least one partially cylindrical shaped surface, which focuses light into a line. To focus light (e.g., sunlight) onto the solar cell 150, a midsection of the cylindrical lens 121 may be thicker than ends of the cylindrical lens 121. Also, the solar cell 150 is disposed at a focal length of the cylindrical lens 121. The upper substrate 120 may be formed of a transparent material such as glass or plastic. Accordingly, light (e.g., sunlight) incident on the upper substrate 120 within a given, desired or predetermined angle range is focused onto the solar cell 150 by being refracted by the cylindrical lens 121.

Still referring to FIGS. 1 and 2, a space 160 between the lower substrate 110 and the cylindrical lens 121 is sealed by a sealant 130. In this example, the space 160 is vacuous or filled with an inert gas, such as neon (Ne) or argon (Ar), so that the solar cell 150 is less affected or not affected by external conditions.

According to at least some example embodiments, a solar cell module may be manufactured by forming the solar cell 150 on the top surface of the lower substrate 110, and then combining or adhering the upper substrate 120 including the cylindrical lens 121 with the lower substrate 110 to cover the solar cell 150.

As described above, according to at least one example embodiment, the upper substrate 120 includes the cylindrical lens 121, which focuses light (e.g., sunlight) onto the solar cell 150. Thus, when light (e.g., sunlight) is incident on the upper substrate 120 at an arbitrary angle, the light (e.g., sunlight) is focused onto the solar cell 150 by the cylindrical lens 121. Accordingly, the efficiency of the solar cell module according to at least this example embodiment may undergo little or no change even when a path of the light (e.g., sunlight) changes. As a result, the efficiency of the solar cell 150 increases. Also, the space 160 between the lower substrate 110 and the cylindrical lens 121 including the solar cell 150 is sealed, and is maintained vacuous or filled with an inert gas, thereby suppressing and/or preventing changes to the characteristics of the solar cell 150 according to external conditions.

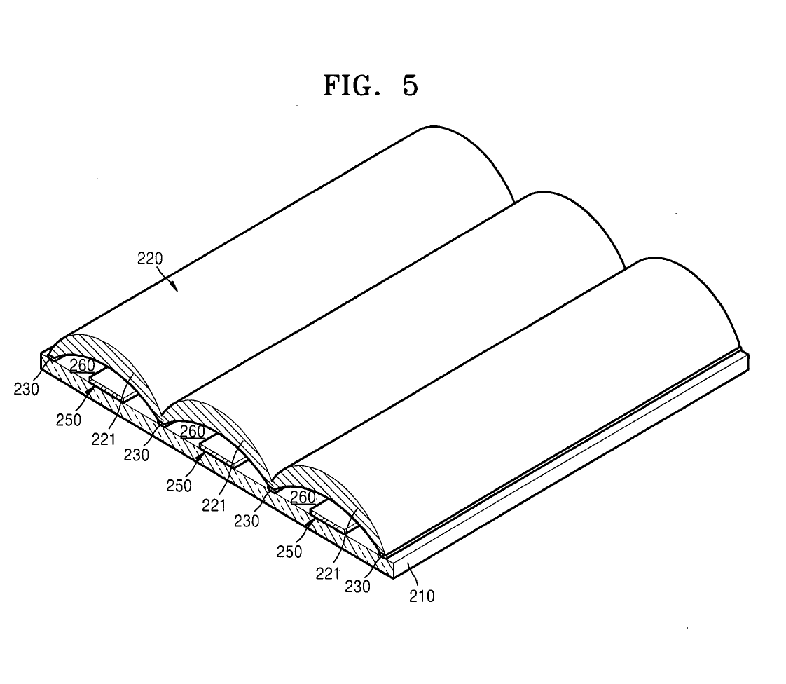

In at least one example embodiment, the upper substrate 120 includes one cylindrical lens 121. But, to manufacture a relatively large solar cell module, an upper substrate 220 may include a plurality of cylindrical lenses 221 as illustrated in FIG. 5.

FIG. 5 is a laid-open perspective view of a solar cell module according to another example embodiment. The solar cell module of FIG. 5 will now be described mainly with regards to differences from the solar cell module of FIG. 1.

Referring to FIG. 5, the solar cell module according to at least this example embodiment includes a lower substrate 210, a plurality of solar cells 250 prepared or formed on the lower substrate 210, and an upper substrate 220 formed on or adhered to the lower substrate 210. The upper substrate 220 covers the solar cells 250.

The solar cells 250 are prepared on a top surface of the lower substrate 210. In this example embodiment, the solar cells 250 are arranged in a stripe form, for example, parallel or substantially parallel to one another. As described above, the solar cells 250 may have a p-n junction structure or a p-i-n junction structure. For example, the solar cells 250 may be Si crystalline solar cells, Si thin film solar cells, CIGS thin film solar cells, CdTe thin film solar cells, III-V group semiconductor solar cells, organic solar cells, etc., but are not limited thereto.

As noted above, the upper substrate 220 is formed over the solar cells 250 to cover the solar cells 250. In at least this example embodiment, the upper substrate 220 includes a plurality of cylindrical lenses 221. Each of the plurality of cylindrical lenses 221 is arranged over a corresponding one of the plurality of solar cells 250 and configured to focus light (e.g., sunlight) onto the corresponding one of the plurality of solar cells 250. To focus light (e.g., sunlight) onto the solar cells 250, each cylindrical lens 221 may have a midsection thicker than both ends of the cylindrical lens 221. Also, the solar cells 250 may be disposed at focal lengths of the cylindrical lenses 221. The upper substrate 220 may be formed of a transparent material such as glass or plastic. Spaces 260 between the lower substrate 210 and the cylindrical lenses 221 are sealed by a sealant 230, and the solar cells 250 are prepared in the spaces 260. In this example, the spaces 260 may be maintained vacuous or filled with an inert gas such as Ne or Ar.

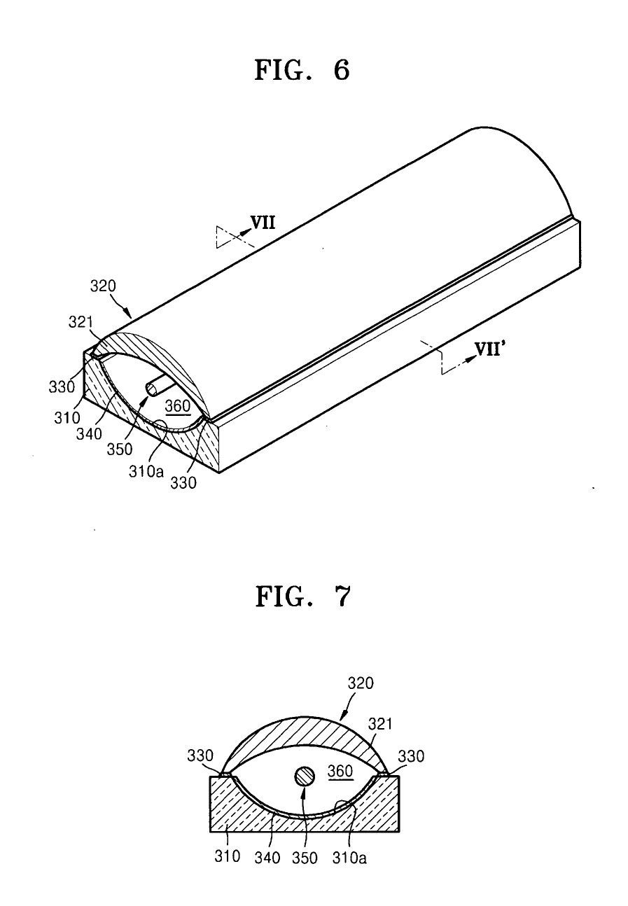

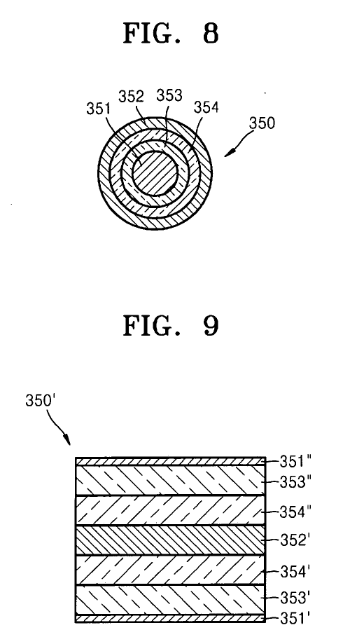

FIG. 6 is a laid-open perspective view illustrating a solar cell module according to another example embodiment. FIG. 7 is a cross-sectional view taken along a line VII-VII′ in FIG. 6. FIG. 8 is a cross-sectional view of an example embodiment of the solar cell 350 shown in FIG. 6.

Referring to FIGS. 6 through 8, the solar cell module includes a lower substrate 310 having a concave surface 310a, a reflective layer 340 formed on the concave surface 310a, an upper substrate 320 including a cylindrical lens 321 prepared or formed on the lower substrate 310, and a solar cell 350 prepared or formed between the reflective layer 340 and the cylindrical lens 321.

The lower substrate 310 may include any one of various materials such as silicon, a glass, a plastic, or a metal. The concave surface 310a corresponding to the cylindrical lens 321 is formed on a top surface of the lower substrate 310, and the reflective layer 340 is formed on the concave surface 310a. The reflective layer 340 reflects light (e.g., sunlight) that penetrates the cylindrical lens 321, but is not focused onto the solar cell 350, toward the solar cell 350. The solar cell 350 is disposed at a focal length of the reflective layer 340. The reflective layer 340 may be a thin metal film including a reflective material such as silver (Ag), aluminum (Al), gold (Au), or platinum (Pt), or a thin dielectric layer.

The upper substrate 320 including the cylindrical lens 321 is prepared or formed on the lower substrate 310. In this example, the cylindrical lens 321 is disposed corresponding to the concave surface 310a. The cylindrical lens 321 focuses light (e.g., sunlight) onto the solar cell 350. Accordingly, a midsection of the cylindrical lens 321 may be thicker than both ends of the cylindrical lens 321. Also, the solar cell 350 is disposed at a focal length of the cylindrical lens 321. The upper substrate 320 may be formed of a transparent material such as a glass or a plastic. Accordingly, light (e.g., sunlight) incident on the upper substrate 320 at an arbitrary angle may be focused onto the solar cell 350 by being refracted by the cylindrical lens 321.

The solar cell 350 may be prepared or formed between the concave surface 310a of the lower substrate 310 and the cylindrical lens 321 of the upper substrate 320. In one example, the solar cell 350 is disposed at a focal length of the cylindrical lens 321 and at a focal length of the reflective layer 340. The solar cell 350 may be supported by a support (not shown), which is formed inside a space 360 between the reflective layer 340 and the cylindrical lens 321. The solar cell 350 may have a circular cross-section and a p-n junction structure as shown, for example, in FIG. 8.

In more detail, referring to the example embodiment shown in FIG. 8, the solar cell 350 has a structure in which a first material layer 353, a second material layer 354, and a second electrode 352 are sequentially disposed on a circumference of a first electrode 351 having a wire shape in the stated order. In this example, the first material layer 353 is a p-type material layer and the second material layer 354 is an n-type material layer. Alternatively, the first material layer may be an n-type material layer 353 and the second material layer 354 may be a p-type material layer. The solar cell 350 may be an Si crystalline solar cell, an Si thin film solar cell, a CIGS thin film solar cell, a CdTe thin film solar cell, a III-V group semiconductor solar cell, an organic solar cell, etc. In another example embodiment, the solar cell 350 may have a p-i-n junction structure. In this case, the solar cell 350 includes an intrinsic material layer (not shown) between the first material layer 353 and the second material layer 354.

FIG. 9 illustrates another example embodiment of a solar cell. The solar cell shown in FIG. 9 may be included in the solar cell module shown in FIG. 6.

Referring to FIG. 9, the solar cell 350′ has a rectangular cross-section. In more detail, a second electrode 352′ is prepared or formed between two first electrodes 351′ and 351″. A first material layer 353′ and a second material layer 354′ are formed between the first electrode 351′ and the second electrode 352′, and a first material layer 353″ and a second material layer 354″ are formed between the first electrode 351″ and the second electrode 352′. Alternatively, the solar cell 350′ may have a p-i-n junction structure. In this example embodiment, an intrinsic material layer (not shown) is formed between the first material layer 353′ and the second material layer 354′ and is formed between the first material layer 353″ and the second material layer 354″.

Referring back to FIGS. 6 and 7, the space 360 between the reflective layer 340 and the cylindrical lens 321, including the solar cell 350, is sealed by a sealant 330. The space 360 may be maintained vacuous or filled with an inert gas, such as Ne or Ar, so that the solar cell 350 is less affected or not affected by external conditions.

As described above, the upper substrate 320 includes the cylindrical lens 321, which the cylindrical lens 321 focuses light (e.g., sunlight) onto the solar cell 350. Thus, when light (e.g., sunlight) is incident on the upper substrate 320 at an arbitrary angle, the light (e.g., sunlight) is focused onto the solar cell 350 by the cylindrical lens 321. Furthermore, by forming the reflective layer 340 on the lower substrate 310, light (e.g., sunlight) that penetrates the cylindrical lens 321, but is not focused onto the solar cell 350, is reflected toward the solar cell 350 by the reflective layer 340. Thus, the efficiency of the solar cell 350 is increased.

The solar cell module according to at least one example embodiment may be manufactured by preparing or forming the lower substrate 310 including the reflective layer 340, preparing or forming the upper substrate 320 including the cylindrical lens 321, disposing the solar cell 350 between the reflective layer 340 and the cylindrical lens 321, and combining or adhering the lower substrate 310 and the upper substrate 320. Alternatively, the solar cell module may be manufactured as described below.

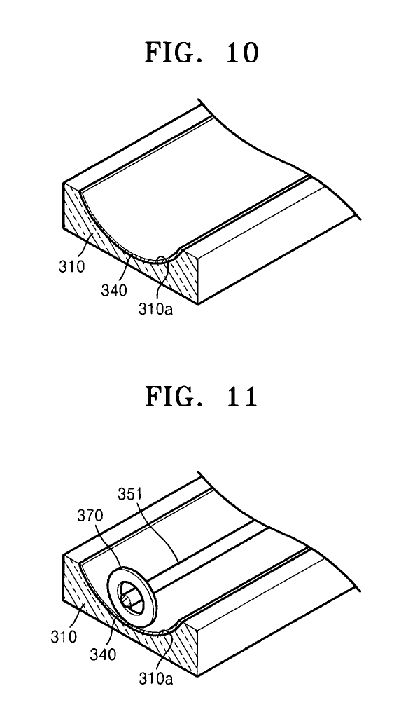

FIGS. 10 and 11 are diagrams for describing a method of manufacturing a solar cell module according to an example embodiment. The method shown in FIGS. 10 and 11 may be used to manufacture the solar cell module illustrated in FIG. 6.

Referring to FIG. 10, the concave surface 310a is formed on the top surface of the lower substrate 310 by processing the lower substrate 310. The reflective layer 340 is then formed on the concave surface 310a. The reflective layer 340 may be formed by depositing a thin metal layer including Ag, Al, Au, Pt, or a thin dielectric layer on the concave surface 310a.

Referring to FIG. 11, the first electrode 351 having a wire shape is prepared in an inner space of the concave surface 310a using a support 370. The first material layer 353 of FIG. 8, the second material layer 354 of FIG. 8, and the second electrode 352 of FIG. 8 are then sequentially deposited on the first electrode 351 in the stated order. For example, a method of depositing the first material layer 353, the second material layer 354, and the second electrode 352 may include a depositing method using thermal electron emission of a vacuum fluorescent display (VFD), a chemical vapor deposition method, a deposition method using a sublimation process according to a temperature difference between an object to be deposited and a source, a deposition method using a linear semiconductor, and a selective deposition method using an infrared (IR) absorber, but are not limited thereto. As such, the solar cell 350 of FIG. 6 is prepared in the inner space of the concave surface 310a. The upper substrate 320 including the cylindrical lens 321 is then combined or adhered with the lower substrate 310. The space 360 between the reflective layer 340 and the cylindrical lens 321 is then sealed. The space 360 may be maintained vacuous or filled with an inert gas.

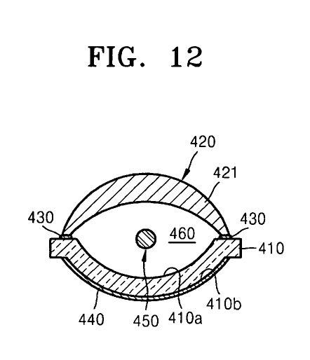

FIG. 12 is a cross-sectional view illustrating a solar cell module according to another example embodiment. The solar cell module will be described mainly with regards to differences from the solar cell modules according to previously described example embodiments.

Referring to FIG. 12, the solar cell module includes a lower substrate 410 having a concave surface 410a and a convex surface 410b, a reflective layer 440 formed on the convex surface 410b, an upper substrate 420 including a cylindrical lens 421 prepared or formed on the lower substrate 410, and a solar cell 450 prepared or formed between the reflective layer 440 and the cylindrical lens 421.

The lower substrate 410 may be a transparent substrate, such as a glass or plastic substrate. The concave surface 410a corresponding to the cylindrical lens 421 is formed on a top surface of the lower substrate 410, and the convex surface 410b corresponding to the concave surface 410a is formed on a bottom surface of the lower substrate 410. The reflective layer 440 is formed on the convex surface 410b. The reflective layer 440 reflects sunlight that penetrates the cylindrical lens 421, but is not focused on the solar cell 450, toward the solar cell 450. Accordingly, the solar cell 450 is disposed at a focal length of the reflective layer 440.

The upper substrate 420 including the cylindrical lens 421 is prepared on the lower substrate 410. In this example, the cylindrical lens 421 is disposed to correspond to the concave surface 410a. A midsection of the cylindrical lens 421 may be thicker than both ends of the cylindrical lens. Also, the solar cell 450 is disposed at a focal length of the cylindrical lens 421.

The solar cell 450 is prepared between the reflective layer 440 and the cylindrical lens 421. And, the solar cell 450 is disposed at the focal length of the cylindrical lens 421 and at the focal length of the reflective layer. Also, a space 460 between the concave surface 410a and the cylindrical lens 421, in which the solar cell 450 is prepared, is sealed by a sealant 430. In this example, the space 460 may be maintained vacuous or filled with an inert gas, such as Ne or Ar, so that the solar cell 450 is less affected or not affected by external conditions.

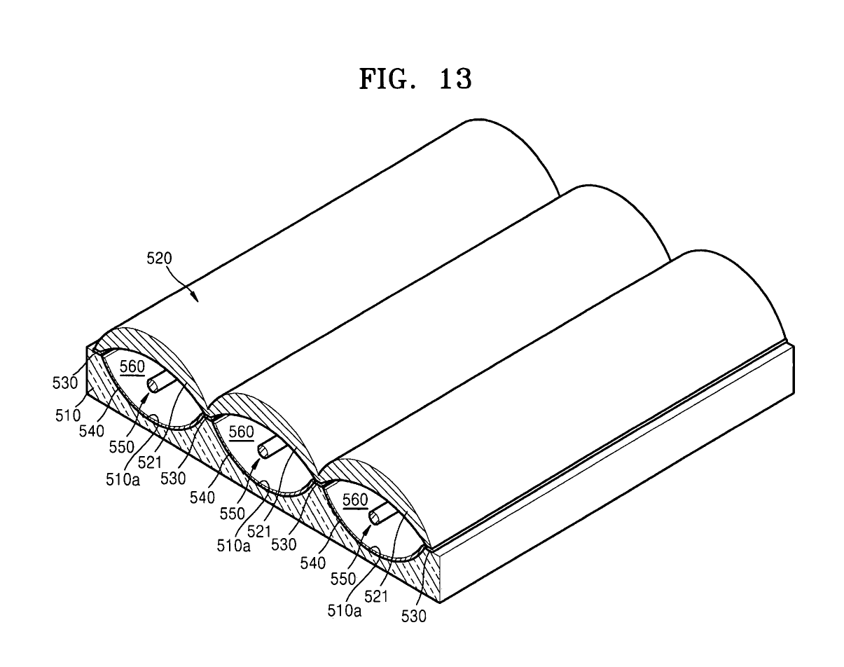

Alternatively, to manufacture a relatively large solar cell module, the solar cell module may include a plurality of cylindrical lenses 521 and a plurality of reflective layers 540 corresponding to the plurality of cylindrical lenses 521 as shown in FIG. 13.

FIG. 13 is a cross-sectional view illustrating a solar cell module according to another example embodiment. The solar cell module according to at least this example embodiment will now be described mainly with regards to difference from the solar cell modules according to previously described example embodiments.

Referring to FIG. 13, the solar cell module according to this example embodiment includes a lower substrate 510 including a plurality of concave surfaces 510a, a plurality of reflective layers 540 formed on the concave surfaces 510a, an upper substrate 520 including a plurality of cylindrical lenses 521 prepared or formed on the lower substrate 510, and a plurality of solar cells 550. Each of the plurality of solar cells is prepared or formed between a reflective layer 540 and corresponding cylindrical lens 521.

The concave surfaces 510a corresponding to the cylindrical lenses 521 are formed on a top surface of the lower substrate 510, and the reflective layers 540 are formed on the concave surfaces 510a. The reflective layers 540 reflect light (e.g., sunlight) that penetrates the cylindrical lens 521, but is not focused onto the solar cells 550, toward the solar cells 550. Accordingly, the solar cells 550 are disposed at focal lengths of the reflective layers 540. Alternatively, as shown in FIG. 12, a plurality of convex surfaces (not shown) may be formed on a bottom surface of the lower substrate 510, and the reflective layers 540 may be formed on the convex surfaces. In this example, the lower substrate 510 may be a transparent substrate.

Still referring to FIG. 13, the upper substrate 520 including the plurality of cylindrical lenses 521 is prepared or formed on the lower substrate 510. Each cylindrical lens 521 is disposed to correspond to a concave surface 510a. And, each cylindrical lens 521 focuses light (e.g., sunlight) onto a corresponding solar cell 550. Accordingly, each midsection of the cylindrical lenses 521 is thicker than both ends of the cylindrical lens 521. Also, the solar cells 550 are disposed at focal lengths of the cylindrical lenses 521. The upper substrate 520 may be formed of a transparent material such as a glass or a plastic.

Each solar cell 550 may be prepared or formed between a reflective layer 540 and corresponding cylindrical lens 521. As described above, the solar cells 550 may have circular or rectangular cross-sections. And, the solar cells 550 may have p-n junction structures or p-i-n junction structures.

Still referring to FIG. 13, spaces 560 between the concave surfaces 510a and the cylindrical lenses 521, in which the solar cells 550 are prepared, are sealed by a sealant 530. The spaces 560 may be maintained vacuous or filled with an inert gas, such as Ne or Ar, so that the solar cells 550 are less or not affected by external conditions.

As described above, according to the one or more example embodiments, a solar cell module includes a cylindrical lens that focuses light (e.g., sunlight) onto a solar cell, and thus, the efficiency of the solar cell module is more uniformly maintained even when a path of the light (e.g., sunlight) changes. Accordingly, the efficiency of the solar cell increases. In addition, a space between a lower substrate and the cylindrical lens, wherein the solar cell is prepared, is sealed thereby suppressing and/or preventing the characteristics of the solar cell from changing according to external conditions.

It should be understood that the example embodiments described herein should be considered in a descriptive sense only and not for purposes of limitation. Descriptions of features or aspects within each example embodiment should typically be considered as available for other similar features or aspects in other example embodiments.

What is claimed is:

1. A solar cell module comprising:
a lower substrate;
an upper substrate disposed on the lower substrate; and
a solar cell disposed between the upper and lower substrates; wherein
the upper substrate is disposed to cover the solar cell, and
the upper substrate includes a cylindrical lens configured to focus incident light onto the solar cell.

2. The solar cell module of claim 1, wherein the solar cell is disposed on the lower substrate.

3. The solar cell module of claim 2, wherein a midsection of the cylindrical lens is thicker than ends of the cylindrical lens.

4. The solar cell module of claim 2, wherein the solar cell is disposed at a focal length of the cylindrical lens.

5. The solar cell module of claim 2, wherein a space between the lower substrate and the cylindrical lens is sealed, and the solar cell is disposed in the space.

6. The solar cell module of claim 5, wherein the sealed space is vacuous or filled with an inert gas.

7. The solar cell module of claim 2, wherein the solar cell has one of a p-n junction structure and a p-i-n junction structure.

8. The solar cell module of claim 2, wherein the solar cell is one of a silicon (Si) crystalline solar cell, an Si thin film solar cell, a copper indium gallium selenide (CIGS) thin film solar cell, a cadmium telluride (CdTe) thin film solar cell, a III-V group semiconductor solar cell, and an organic solar cell.

9. The solar cell module of claim 1, further comprising:
a reflective layer formed on the lower substrate; wherein
the solar cell is disposed in a space between the lower substrate and the cylindrical lens.

10. The solar cell module of claim 9, wherein the cylindrical lens focuses the incident light onto the solar cell, and the reflective layer reflects incident light that penetrates the cylindrical lens, but is not focused onto the solar cell by the cylindrical lens, toward the solar cell.

11. The solar cell module of claim 9, wherein a midsection of the cylindrical lens is thicker than ends of the cylindrical lens thereof.

12. The solar cell module of claim 9, wherein the solar cell is disposed at a focal length of the cylindrical lens and at a focal length of the reflective layer.

13. The solar cell module of claim 9, wherein the reflective layer is one of a thin metal layer and a thin dielectric layer.

14. The solar cell module of claim 9, wherein a top surface of the lower substrate corresponding to the cylindrical lens is concave.

15. The solar cell module of claim 14, wherein the reflective layer is formed on the concave surface.

16. The solar cell module of claim 14, wherein a bottom surface of the lower substrate is convex and the reflective layer is formed on the convex surface.

17. The solar cell module of claim 16, wherein the lower substrate is a transparent substrate.

18. The solar cell module of claim 9, wherein a space between the lower substrate and the cylindrical lens is sealed, and the solar cell is disposed within the space.

19. The solar cell module of claim 9, wherein a cross-section of the solar cell is one of circular and rectangular.

20. The solar cell module of claim 9, wherein the solar cell has one of a p-n junction structure and a p-i-n junction structure.

21. A method of manufacturing the solar cell module of claim 9, the method comprising:
forming a reflective layer on a surface of the lower substrate, the surface being one of a concave and convex surface;
preparing a first electrode having a wire shape;
manufacturing the solar cell by sequentially depositing a first material layer, a second material layer, and a second electrode onto the first electrode; and
adhering the upper substrate including the cylindrical lens on the lower substrate.

22. The method of claim 21, wherein a midsection of the cylindrical lens is thicker than ends of the cylindrical lens.

23. The method of claim 21, wherein the solar cell is prepared at a focal length of the cylindrical lens and at a focal length of the reflective layer.

24. The method of claim 21, wherein the reflective layer is formed on the concave surface.

25. The method of claim 21, wherein the surface of the lower substrate is a convex, bottom surface of the lower substrate, and the reflective layer is formed on the convex surface.
